(19) United States
(12) Patent Application Publication
(10) Pub. No.: US 2003/0032312 A1
(43) Pub. Date: Feb. 13, 2003

(54) Constitution connector

(76) Inventor: Chao-Chiu Liu, Hsin-Chu (TW)

Correspondence Address: PAI AND CHANG, PLLC, 10212 FIFTH AVE NE, SUITE 250, SEATTLE, WA, 98125, US

(21) Appl. No.: 09/927,358

(22) Filed: Aug. 13, 2001

(51) Int. Cl. H05K 1/00

(52) U.S. Cl. 439/79

(57) ABSTRACT

The object of the present invention is an improved constitution of connector having a case and the chip special constitution fabricated to minimize the thickness and fold closely with a fixed plate and an upper build to comprise the connector; the total height maintains at a set standard, the connector installs directly on the pc board to keep the set thickness, and enables it to embed and fix in the cartridge, to plug in current terminal directly and facilitate the use without using the switch, simplifying the component to reduce the cost.

### FIELD OF THE INVENTION

This invention relates to an improved constitution connector, more particularly to a case of the connector and the chip combining a low constitution, the whole embodiment arranged on the pc board enables to embed in the PCMCIA CARD, thus facilitating easy to carry when collocate the improved constitution connector of the information device.

### DESCRIPTION OF THE RELATED ART

It is well known that The conventional connector is arranged on the pc board, comprising two methods including assembling part and mounting part, and the general structure is an embodiment formed with the insulated engineering plastic, fixed and covered with an iron crust, such as the numbered IEEE 1394 connector, please referring to FIG. 1, there is a case 1 set on a fixed plate 2, numbers of chips 3 forming multiple layers of winding, to plug in the outlet and holes of the case 1, the chip 3 wind like the ladder and ascend gradually, the height forming between high position and low position is considerably large, the height of the case 1 also has to increase proportionally, at the same time, there is a shell 5 set between the housing 4 of the fixed plate 2 and the case 1, the shell 5 itself has space and also distance from the case 1, so the housing 4 must increase enough height of space 6 to contain the case 1 and the shell 5, therefore, the height of the connector of IEEE 1394 is quite large after fabricated with the conventional use of the fixed plate 2 and the case 1, thus, the present connectors of IEEE 1394 right now are all greater than 5 MM.

The conventional connector fabricates on the pc board by assembling part and mounting, limited to the structure of the connector itself, the thickness of the case 1 and the fixed plate 2 is very big, the height is far more bigger than 5 mm, however, the current information device uses PCMCIA CARD, whose cartridge space is all limited within 5 MM and the thickness of conventional connector fabricating on the PC Board by assembling part and mounting is far more greater than 5 mm, so that the conventional use can't be embedded and fixed directly on the cartridge connecting the inner circuit of the PCMCIA CARD, therefore, connectors are all fabricated on a switch, whose volume is big and thick, the switch has a joint to connect the PCMCIA CARD, when the PCMCIA CARD is plugged in the information device, the current terminal can be plugged in the outlet of the switch to connect the device for use.

However, the volume of the switch is all big and thick, therefore, it is inconvenient to store or to use, no doubt, to the small and thin digital product in modern day, it is a great impediment needed to be improved right away especially to carry such a big and thick component is very disturbing; moreover, the switch needs many assemblies so it will result in more extra cost, of course, the relative price will increase too, at the same time, they have some difference because of different companies, and types. Please referring to attachment 1 which is the product catalogue of PCMCIA CARD with switches, therefore, it can't apply to all the types, all these defects cause the users' inconvenience.

### SUMMARY OF THE INVENTION

The object of the present invention of the improved constitution connector is to set up the height of the fixed plate, the case collocating the chips to be low and to decrease the thickness, which set on the fixed plate with the upper build to fabricate the connector in order to make the whole connector with low thickness.

The second object of the present invention of the improved constitution connector is to embed the connector into the PC Board fixedly and mountedly, the connector after combining remains low thickness and the same height to embed into the cartridge and connect terminal directly.

According to the present invention, the improved constitution connector includes an insulated case, many chips, a fixed plate, an upper build.

The case has a channel in one end and an outlet in the other end, said channel connecting a trough hole, said trough hole connecting a fixed trough on said outlet; the trough hole is pervious down and up, the front end of said case has a housing surrounded said outlet, the housing have a pervious trough corresponding to the upper side of said outlet;

The chips have a connecting end stretching to a middle section, the other side of said middle section inclined downwards and upwards to collocate and to stretch in bended form, the middle section inclined downwards and upwards to become short and low, and an end side has a contacting end; the middle section of the chip connect said channel and said fixed trough of the case, the middle section inclined downwards and upwards and protruded into the trough hole in bended form, the case decreased its thickness corresponding to the height of said middle section;

The fixed plate has a frame and stretched out two side planks, and both the side plank have a fixed hole;

The upper build has a flexible element, the upper build fix the case, the upper build connecting the frame and enabling said flexible element to put in the pervious trough, enabling the upper build to level and connect said fixed plate and to stick on the case tightly to maintain lower thickness.

### BRIEF DESCRIPTION OF THE DRAWINGS

Other features and advantages of the present invention will become apparent in the following detailed description of the preferred embodiment of the invention, with reference to the accompanying drawings, in which:

FIG. 1 is a schematic view illustrating the conventional connector;

FIG. 2 is a schematic view illustrating the case and the first preferred embodiment of this invention;

FIG. 3 is a schematic section view of the case of the first preferred embodiment of FIG. 2;

FIG. 4 is a perspective view of the chip of the first preferred embodiment;

FIG. 5 is a perspective view of the IEEE 1394 fabricated by the first preferred embodiment of this invention;

FIG. 6 is a diagram of the first preferred embodiment illustrating this invention of the connector constituted on the pc board; and

FIG. 7 is a front side view of the connector of the first preferred embodiment of this invention of FIG. 6; and

FIG. 8 is a top view of the connector of the first preferred embodiment of this invention of FIG. 6;

FIG. 9 is a schematic view illustrating the IEEE 1394 connector on the pc board and fabricated in the cartridge;

FIG. 10 is a schematic view illustrating the IEEE 1394 connector on the cartridge; and

FIG. 11 is a schematic view illustrating the IEEE 1394 of the first preferred embodiment of this invention on the cartridge.

FIG. 12 is a part of a schematic view of the first preferred embodiment of IEEE 1394 connector.

### DETAILED DESCRIPTION OF THE PREFERRED EMBODIMENT

Please referring to FIG. 2 and FIG. 5, a preferred embodiment of the improved constitution connector according to the present invention is shown to include a case 20, four chips 30, a fixed plate 40 and an upper build 50:

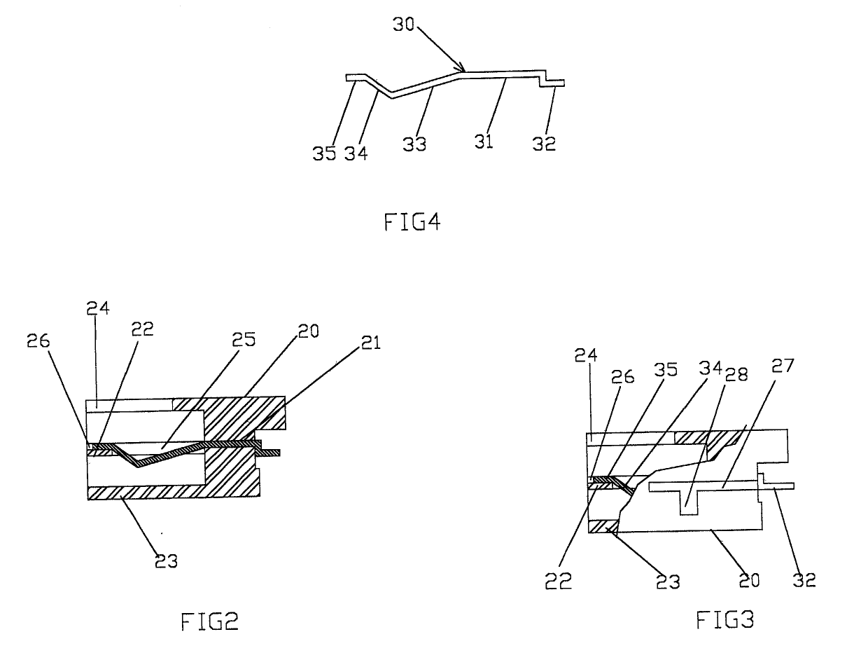

The case 20, please referring to FIGS. 2, 3, is formed of a plastic nonconductor, there are four channels 21 arranged at the same intervals in one side, in the other side are an outlet 22, one housing 23 of the case 20 in front side winds hollowly the outside of the outlet 22, on the housing 23 has a pervious trough 24; on the outlet 22 are four fixed troughs 26 and connecting a pervious trough hole 25 one by one, the trough hole 25 connects the channel 21 and corresponds to the fixed trough 26 in the same height; in the middle of two sides of the case 20 stretching out two planks 27 and in each bottom side is a protruding point 28.

The chips 30, please referring to FIG. 2, FIG. 4, there are four branches, which are made of the conductive metal materials and correspond to the channel 21 of the case 20, the channel 21 protrudes from an end side of one of the middle section 31 and bends downwards where is a connecting end 32, the other side of this middle section 31 bends to stretch out to form a bended prolonging section 33 inclined downwards, the end side of this prolonging section 33 is a elongated section 34 inclined upwards, whose end side bends a contacting end 35, and the contacting end 35 straddles on the fixed trough 26, because the prolonging section 33 inclined downwards and the elongated section 34 inclined upwards, the middle section 31 bends upwards and downwards to neutralize the accumulated height, and the height of the middle section 31 reduces greatly.

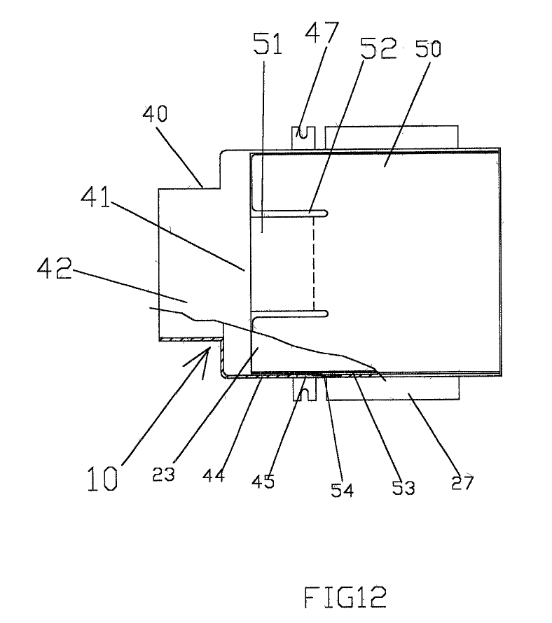

The fixed plate 40, please referring to FIG. 5, FIG. 6 and FIG. 11, is a certain height of a fixed loop 42, the height corresponds to the thickness of a current terminal 80, about 4.2 mm, the end side of the fixed loop 42 stretches out a frame 41 with a certain height which is set within 5 mm in this invention, the frame 41 can contain the thickness of the case 20 and make them embed and fix with each other. There is a frame 41 corresponding the thickness of the case 20, and to make both can embed each other, in front of the frame 41 elongating a fixed loop 42, in the two back sides of the frame 41 stretching out two side planks 44 to hold each other, and both the side plank 44 have a rectangular fixed hole 45, the side plank 44 has a stage 46, and at the under side of the fixed hole 45 all has an outward bended conductor 47.

The upper build 50, please referring to FIG. 5, FIG. 8 and FIG. 9 and FIG. 12, is a flat plank enable to put between the frame 41 of the fixed plate 40 and the side plank 44, the front end has a plank bending downwards to form a flexible element 51, corresponding the flexible element is a cross way 52 at both sides to make the flexible element 51 to have bigger elastic deformation and better flexibility, the upper build 50 has two bended downwards folds 53 at both sides, the fold 53 has a stretch-out, inclined outward hook 54.

This invention enables to utilize the middle section 31 of the chip 30 corresponding and connecting the channel 21 of the case 20, please referring to FIG. 2, FIG. 4, and the channel 21 connect the pervious trough hole 26, the elongated section 33 and the prolonging section 34 are put in the trough hole 25 in the bended form and protruded downwards, the contacting end 35 straddle on the fixed trough 26 upwards, the elongated section 33 of the middle section 31, prolonging section 34 bend up and below, the elongated section 33, the prolonging section 34 inclined upwards and downwards to compensate each other, to make the position difference of the high point and low point of the middle section 31 of the chip 30 close and to make the height decrease greatly, the height of the case 20 also decreased greatly corresponding to the middle section 31, to make the thickness of the case 20 far less than 5 mm.

For the combined using, please referring to FIG. 5, FIG. 6, is to put the outlet 22 of the case 20 in the frame 41 of the fixed plate 40, and to form the embedded fixture, the plank 27 of the case 20 connect the stage 46 of the side plank 44 to fix the position, at the moment, to make the upper build 50 to embed in the frame 41, please referring to FIG. 12, at the same time, the hook 54 of the fold 53 corresponds to the fixed hole 45 to connect, to make the upper build 50 connect with the frame 41 and to cover the upside of the case 20, then complete fabricating the connector of the number IEEE 1394.

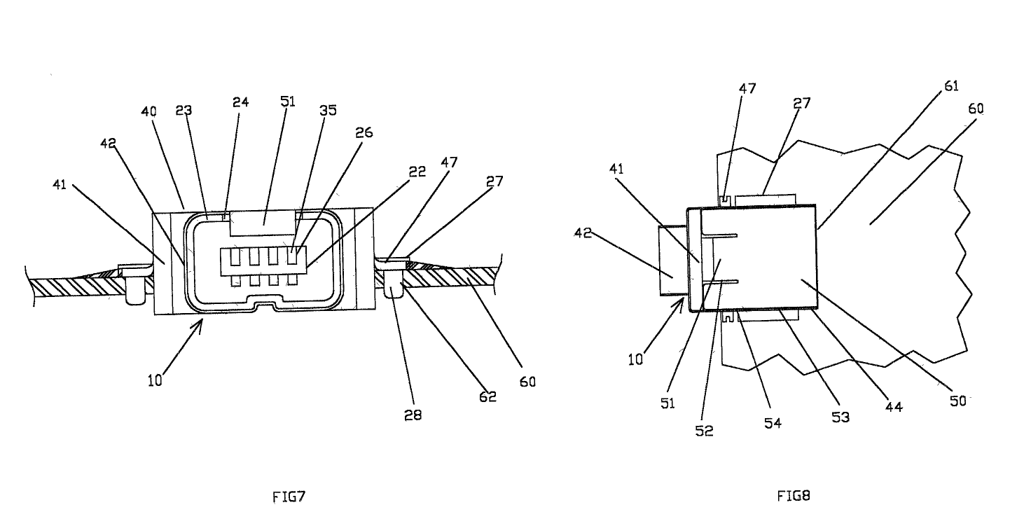

From above description, the invention is known for its special constitution by collocating the trough 21 of the case 20, trough hole 25, and fixed trough 26, and the shapes of the prolonging section 33 of the chip 30, elongating section 34 and the contacting end 35, lower more greatly than the height of the conventional use so that the height after combining the chip 30 and the case 20, please referring to FIG. 7, the case 20 is set on the fixed plate 40 to make the upper build 50 cover up the fixed plate 40.

In this invention of the connector 10 of the number IEEE 1934, the flexible element 51 of the upper build 50 put in the pervious trough 24 of the housing 23, the upper build 50 was able to level the frame 41, the upper build 50 connects the upper side of the case 20 and will not result in the intervals and the space, therefore, there will not be the hollow space to cause the accumulation of the height, so the case 20 and the upper build 50 can fabricate on the fixed plate 40 completely, the total height is leveled with the fixed plate 40, which is lower than 5 mm and within the set standard maintain.

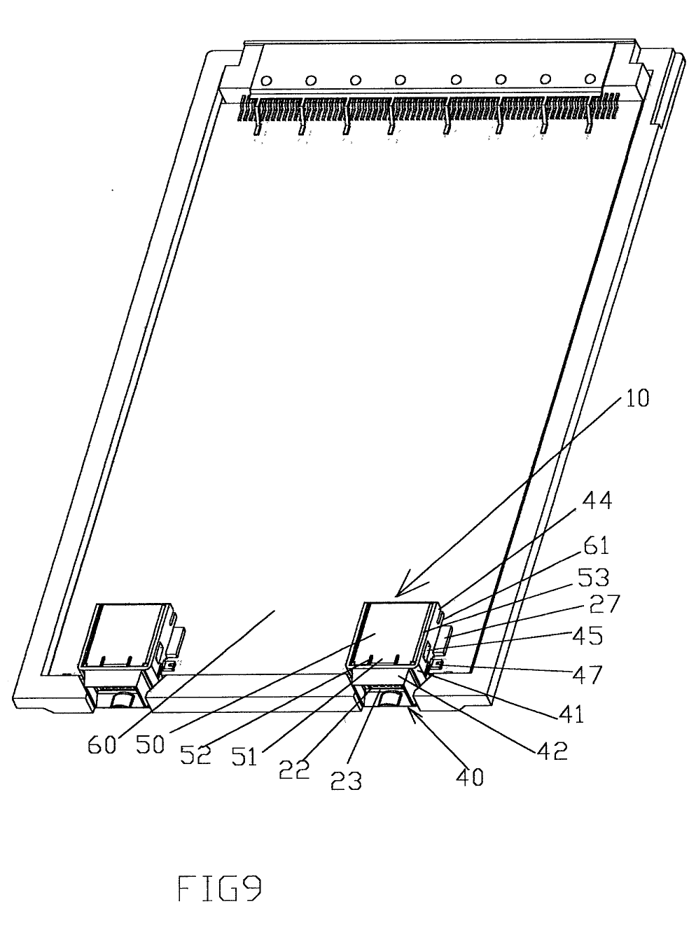

The fabrication of this invention is the unity of the connector 10 of the number IEEE 1394, please referring to FIG. 6, FIG. 8, FIG. 9, when fabricating it, in a particular position of a pc board 60 has a gap 61, and when the unity of the connector fabricating in the particular position of the pc board 60, the case 20 suit the gap 61, the plank 27 straddles and connects the side of the gap 61, and the protruding point 28 connect the small hole 62 to form the fixed position. The conductor 47 and the connecting point of the chip 30 touch the tin cream on the surface of the pc board 60 directly.

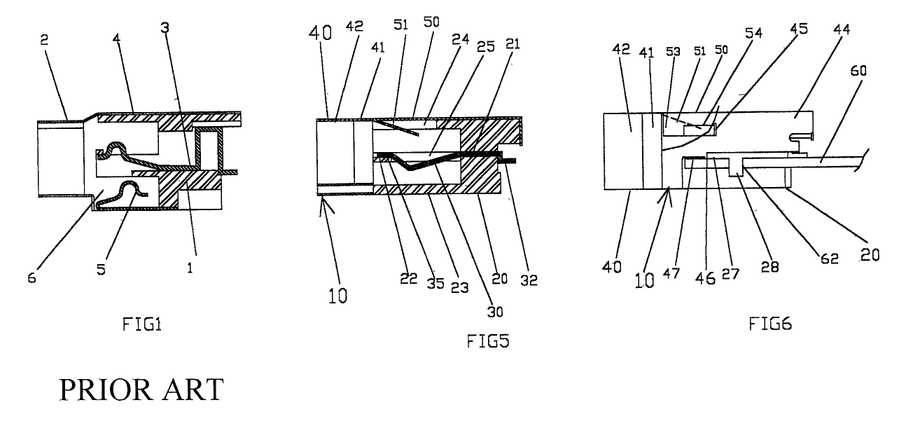

By fabricating the unity of connector 10 of the number IEEE 1394 on the pc Board 60, the total height of the fired plate 40 and smaller than 5 mm in thickness, the conventional fixed plate is far bigger than 5 mm because it protrudes like ladders, please comparing with FIG. 1 and FIG. 5, obviously to know the weakness that the height when the conventional connector fabricating on the PC Board is far bigger than 5 mm.

With the case 20 combining the gap 61 of the pc board 60, the case 20 will absolutely not pile on the pc board 60, will not have the disadvantage of increasing the total thickness, the fabrication of this invention is unity of the connector 10 of the number IEEE 1934 fabricating on the pc board 60, the total height is merely the total amount of the case 20 and the upper build 50, and less than 5 mm, please referring to FIG. 1, FIG. 5 to compare, obviously that conventional body frame fabricating on the side of the pc board and piling up, however, the conventional connector will cause the disadvantages of accumulating the height of the pc board and forming the thickness far more than 5 mm, on the contrary, the case 20 of this invention straddles and connects the gap 61 of the pc board 60 directly, without being influenced by the thickness of the pc board 60 at all, the connector 10 of this invention fabricates, on the PC Board in same height and maintains within 5 mm, and the conductor 47 and the connecting point of the chip 30 touch the tin cream and are soldered fixedly, the protruding point 28 connects the small hole 62 to fix the position, the connector maintains solid on the pc board 60.

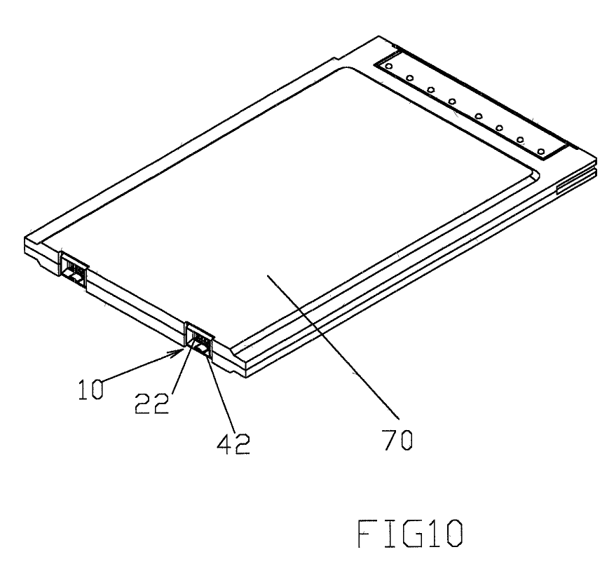

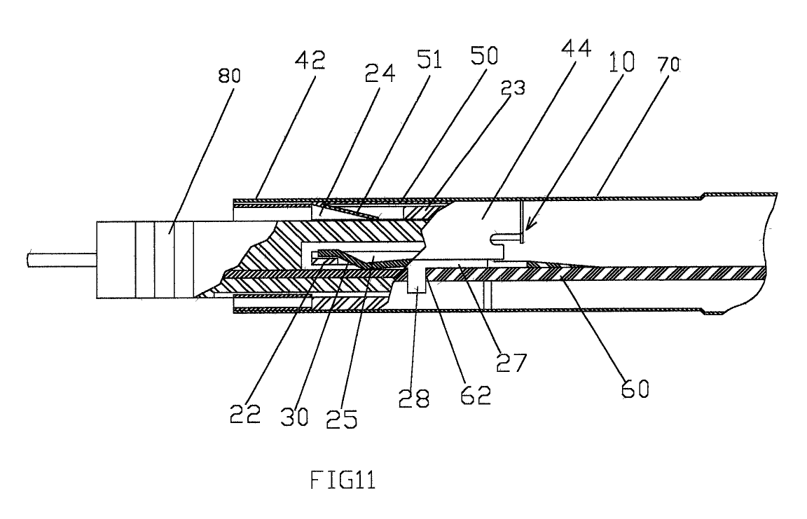

From the above description, it is understood clearly that with the special structure collocated by the channel 21 of the case 20, the pervious trough 25, and the fixed trough 26, the shapes of the prolonging section of the chip 30, elongated section 34 and the contacting end 35, the height after combining the chip 30 and the case 20 is decreased greatly than the conventional knowledge, please referring to FIG. 7, and the case 20 levels and covered with the fixed plate 40 and the upper build 50, the height when the connector 10 of this invention equips on the pc board is all the same and keeps within the set thickness 5 mm; the present cartridge 70 of PCMCIA CARD, CardBus, Compact Flash I/O and so on is limited in 5 mm in height, please referring to FIG. 9, FIG. 10 and FIG. 11, the connector 10 of this invention number IEEE 1394 fabricating on the pc board 60 enables to collocate the height of the present cartridge 70 of PCMCIA CARD, CardBus and Compact Flash I/O and so on, to make the connector 10 fabricating on the pc board and embedding in the cartridge 70 directly, connecting the inner circuit, there is no need to describe the conventional art.

The connector 10 of this invention number IEEE 1394 straddles and connects on the gap 61 of the pc board 60, therefore it can embed in the cartridge 70 of the PCMCIA CARD, please referring to FIG. 10, FIG. 11, and can insert the PCMCIA CARD into the notebooks, the PDA or the carry-on information equipment when using, enabling to connect the current terminal 80 and improve the disadvantage of connecting the switch and the problem hard to store because of the big volume of the switch, this will make PCMCIA CARD easier to carry and very suitable for the carry-on information equipment, and fit the digital need.

It is worth to mention that, please referring to FIG. 7, FIG. 11, when the connector 10 of this invention installs on the pc board and embeds in the cartridge 70 of the PCMCIA CARD, the current terminal 80 matches the fixed loop 42 of the fixed plate 40, the top of the terminal 80 leans to the flexible element 51 of the upper build 50, and the upper build 50 is forced to move upwards, please referring FIG. 11 and FIG. 12, it will make the front side of the upper build 50 touch the cartridge 70 steadily and assure a good ground connection, moreover, better flexible material could be chose through the upper build 50 to make sure the appropriate flexible match.

While the present invention has been described in connection with what is considered the most practical and preferred embodiment, it is understood that this invention is not limited to the disclosed embodiment but is intended to cover various arrangements included within the spirit and scope of the broadest interpretations and equivalent arrangements.

I claim:

1. An improved constitution connector, comprising:
a fixed plate has a fixed loop of a certain height to connect a terminal, in one side of said fixed loop has a frame of a set height;
a case, is formed of insulation, and has a housing of a short thickness corresponding the thickness of said frame, said frame can contain said case and connect each other to embed fixedly, in front side of said housing has an outlet, said case has many channels, said outlet connecting said channels;
many chips, have a connecting end stretching to a middle section, the other side of said middle section inclined downwards and upwards to collocate stretched in bended form, and an end side has a contacting end; said middle section of the chip inclined downwards and upwards to become short and low to connect said channel of said case;
an upper build is set on said frame of said fixed plate level and fixedly, in front side of said upper build has a flexible element, said front side and flexible element can move downwards and upwards to make the terminal connect said outlet, said front side and flexible element can adjust their position to fix said terminal.

2. The improved constitution connector as claimed in claim 1, wherein, the front end of said housing of said case surrounds said outlet hollowly, said housing having a pervious trough corresponding to the upper side of said outlet; said upper build connecting said frame, said flexible element is put on said pervious trough, enabling said upper build to level and connect said fixed plate and to stick on said case tightly to maintain lower thickness.

3. The improved constitution connector as claimed in claim 1, wherein, said frame stretches out two planks said upper build has connects said frame and connects said planks, said front side of said upper build and said flexible element can move downwards and upwards appropriately form a fixed position.

4. The improved constitution connector as claimed in claim 2, wherein, said frame stretches out two planks said upper build has connects said frame and connects said planks, said front side of said upper build and said flexible element can move downwards and upwards appropriately form a fixed position.

5. The improved constitution connector as claimed in claim 3, wherein, said two planks of said frame has a fixed hole, two sides of said upper build has two hook, said two hooks connect said fixed hole to make said upper build easy to set on said fixed plate and cover said case.

6. The improved constitution connector as claimed in claim 4, wherein, said two planks of said frame has a fixed hole, two sides of said upper build has two hook, said two hooks connect said fixed hole to make said upper build easy to set on said fixed plate and cover said case.

7. The improved constitution connector as claimed in claim 1, wherein, the two sides of said case near to the center have a plank, said plank straddles on a fixed position of a gap of a pc board.

8. The improved constitution connector as claimed in claim 2, wherein, the two sides of said case near to the center have a plank, said plank straddles on a fixed position of a gap of a pc board.

9. The improved constitution connector as claimed in claim 7, wherein, said planks each of sides of said case have a bulge in the bottom, said bulge connecting the small holes on said pc board to fix.

10. The improved constitution connector as claimed in claim 8, wherein, said planks each of sides of said case have a bulge in the bottom, said bulge connecting the small holes on said pc board to fix.

11. The improved constitution connector as claimed in claim 1, wherein, said chip mounts on said channel and said trough hole of said case to enable said middle section to incline downwards and upwards and to protrude out said trough in bended form, said case decreased its thickness corresponding to said middle section of said chip, said case connecting said frame of said fixed plate, said upper build leveling and connecting the fixed plate, covering said case to form the connector number IEEE 1394.

12. The improved constitution connector as claimed in claim 2, wherein, said chip mounts on said channel and said trough hole of said case to enable said middle section to incline downwards and upwards and to protrude out said trough in bended form, said case decreased its thickness corresponding to said middle section of said chip, said case connecting said frame of said fixed plate, said upper build leveling and connecting the fixed plate, covering said case to form the connector number IEEE 1394.

13. The improved constitution connector as claimed in claim 11, wherein, said case stick on said upper build tightly to connect said fixed plate and to fabricate the numbered IEEE 1394 connector, and said case straddles on the gap of said pc board to maintain the total thickness of said case and said upper build and enable it to embed in various kind of the cartridge to provide a terminal to connect said outlet of said case.

14. The improved constitution connector as claimed in claim 12, wherein, said case stick on said upper build tightly to connect said fixed plate and to fabricate the numbered IEEE 1394 connector, and said case straddles on the gap of said pc board to maintain the total thickness of said case and said upper build and enable it to embed in various kind of the cartridge to provide a terminal to connect said outlet of said case.
